(19) United States
(12) Patent Application Publication
(10) Pub. No.: US 2011/0265850 A1
(43) Pub. Date: Nov. 3, 2011

(54) SOLAR CELL MODULE

(75) Inventors: Chen-Liang Liao, Tainan City (TW); Chih-Hsiung Chang, Tainan City (TW); Yu-Chun Peng, Tainan City (TW); Yi-Kai Lin, Tainan City (TW)

(73) Assignee: AURIA SOLAR CO., LTD., Tainan City (TW)

(21) Appl. No.: 13/184,033

(22) Filed: Jul. 15, 2011

(30) Foreign Application Priority Data
Jun. 14, 2011 (TW) 100120682

(51) Int. Cl. H01L 31/05

(52) U.S. Cl. 136/244

(57) ABSTRACT

A solar cell module. In one embodiment, the solar cell module includes a substrate, a battery unit, a first strip electrode and a second strip electrode. The substrate has a plurality of power generation zones and at least one cutting zone, and the cutting zone is located among the power generation zones. The battery unit is disposed on the power generation zones and the cutting zones of the substrate. The first strip electrode is disposed on the battery unit, and located at a first end power generation zone of the power generation zones. The second strip electrode is disposed on the battery unit, and located at a second end power generation zone of the power generation zones.

### CROSS-REFERENCE TO RELATED APPLICATIONS

This non-provisional application claims priority under 35 U.S.C. §119(a) on Patent Application No. 100120682 filed in Taiwan (R.O.C) on Jun. 14, 2011, the entire contents of which are hereby incorporated by reference.

### FIELD OF THE INVENTION

The present invention relates to a solar cell module, and more particularly to a solar cell module capable of saving costs and enhancing power generation efficiency.

### BACKGROUND OF THE INVENTION

As the energy demands increase day by day, the use of the so-called renewable energy becomes a very important subject in the current energy development. The renewable energy refers to the theoretically inexhaustible natural energy, such as solar energy, wind energy, water energy, tidal energy or biomass energy. In recent years, the utilization of the solar energy becomes a very important and popular part in the researches on the energy development.

Usually the solar cell module is constructed by arranging battery units capable of optical-to-electrical (O/E) conversion as many as possible on a substrate, so as to increase the area exposed to light, thereby enhancing the power generation efficiency of the entire solar cell module, and then by using two strip electrodes to collect currents generated by the entire solar cell module. Generally, the strip electrodes are disposed on the two sides of multiple battery units, so as to collect the currents generated by the multiple battery units.

FIG. 1 is a schematic plan view of a solar cell module in the prior art; and FIG. 2 is a schematic cross-sectional view of segment a-a in FIG. 1. Referring to FIG. 1 and FIG. 2, a solar cell module PA100 includes a substrate PA1, a first electrode layer PA2, an active layer PA3, a second electrode layer PA4, a first strip electrode PA5 and a second strip electrode PA6.

The first electrode layer PA2 is stacked on the substrate PA1, the active layer PA3 is stacked on the first electrode layer PA2, and the second electrode layer PA4 is stacked on the active layer PA3. The first strip electrode PA5 and the second strip electrode PA6 are disposed respectively on the two sides of the second electrode layer PA4. The first electrode layer PA2, the active layer PA3 and the second electrode layer PA4 form a plurality of power generation zones P1 to Pn and a plurality of cutting zones O1 to On-1 through multiple cutting streets. When the first strip electrode PA5 and the second strip electrode PA6 are connected to an external load or an electronic device, as the first strip electrode PA5 is located at the power generation zone P1, and the active layer PA3 and the first electrode layer PA2 in the P1 zone are not in the circuit formed by the first strip electrode PA5 and the second strip electrode PA6, and therefore, the active layer PA3 located at the power generation zone P1 is incapable of supplying a current.

Moreover, the active layer PA3 and the first electrode layer PA2 below the second strip electrode PA6 are not in the circuit formed by the first strip electrode PA5 and the second strip electrode PA6 either, and therefore, an ineffective zone N without current generation is formed in the second strip electrode PA6.

However, when the solar cell module PA100 is serially connected to other solar cell modules, the first electrode layer PA2 in the power generation zone P1 is serially connected to other battery units, so that the active layer PA3 in the power generation zone P1 is capable of generating a current through the O/E conversion. Even if the second strip electrode PA6 is serially connected to other battery units, the active layer PA3 in the ineffective zone N is still outside the circuit and therefore is incapable of generating a current through the O/E conversion.

It can be known from the above description that in the solar cell module PA100 in the prior art, the active layer PA3 in the ineffective zone N is incapable of generating a current, therefore causing a waste of materials and reduction of the power generation area.

Therefore, the inventor of the present invention thinks it necessary to develop a solar cell module that effectively increases the power generation area and reduces the waste of materials.

### SUMMARY OF THE INVENTION

In one aspect, the technical problems and objectives of the present invention are as follows.

It can be known from the above description that in the prior art, it is usually necessary to provide the solar cell module with a first strip electrode and a second strip electrode to guide a current into a load or an electronic device. However, the zone disposed with the second strip electrode is usually incapable of supplying the current because an active layer below the second strip electrode is not in a circuit formed by the first strip electrode and the second strip electrode, thereby causing a waste of materials and reduction of a power generation area.

In order to solve the above problem, in one aspect, a main objective of the present invention is to provide a solar cell module, in which the second strip electrode is disposed on the power generation zone, and the active layer, the first electrode layer and the second electrode layer in the ineffective zone are omitted. Therefore, the power generation area is relatively increased, and the waste of materials is reduced at the same time.

In one aspect, the technical solution of the present invention is as follows.

In one embodiment, the present invention provides a solar cell module, which includes a substrate, a battery unit, a first strip electrode and a second strip electrode. The substrate has a plurality of power generation zones and at least one cutting zone, and the cutting zone is located among the power generation zones. The battery unit is disposed on the power generation zones and the cutting zones of the substrate. The first strip electrode is disposed on the battery unit, and the first strip electrode is located at a first end power generation zone of the power generation zones. The second strip electrode is disposed on the battery unit, and the second strip electrode is located at a second end power generation zone of the power generation zones.

In a preferred embodiment of the present invention, the battery unit includes a first electrode layer, an active layer and a second electrode layer. The first electrode layer, the active layer and the second electrode layer are disposed in order on the power generation zones and the cutting zones of the substrate. The first strip electrode and the second strip electrode are disposed on the second electrode layer. In the preferred embodiment of the present invention, the first electrode layer has a first opening located at the cutting zone; and the active layer is disposed on the first electrode layer and the substrate exposed from the first opening. The active layer has a second opening located at the cutting zone and a third opening located at the cutting zone; and the second electrode layer is disposed on the active layer and the first electrode layer exposed from the second opening. The second electrode layer has a fourth opening connected to the third opening.

In the preferred embodiment of the present invention, the active layer is a Si-based stack structure, and the stack structure is a monolayer stack structure or a multi-layer stack structure. In the preferred embodiment, the material of the active layer is selected from amorphous silicon or microcrystalline silicon.

In another preferred embodiment of the present invention, the active layer is a compound-based junction structure, and the junction structure may be a single junction structure or a multi-junction structure. In the preferred embodiment of the present invention, the material of the active layer is selected from compounds of Group IIIA-VA elements, compounds of Group IIA-VIA elements or multi-element compounds.

In the preferred embodiments of the present invention, the materials of the first strip electrode and the second strip electrode are metallic conductors.

Compared with the prior art, among other things, the present invention has the following effects.

It can be known from the above description that compared with the solar cell module in the prior art, in the solar cell module according to the present invention, the first electrode layer, the active layer and the second electrode layer in the ineffective zone are omitted, therefore reducing the waste of materials. Also, within the limited area of the substrate, the omission of the first electrode layer, the active layer and the second electrode layer in the ineffective zone can relatively increase the power generation area of the power generation zone, thereby further enhancing the power generation efficiency of the solar cell module.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a schematic plan view of a solar cell module in the prior art;

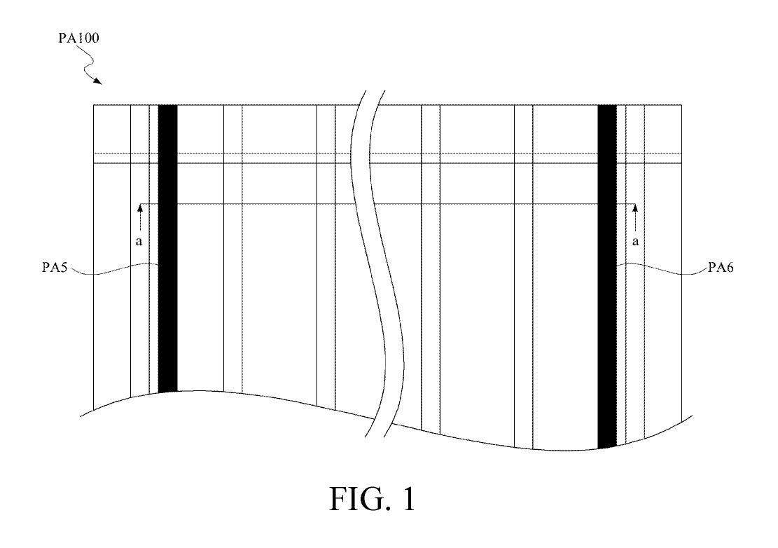

FIG. 2 is a schematic cross-sectional view of segment a-a in FIG. 1;

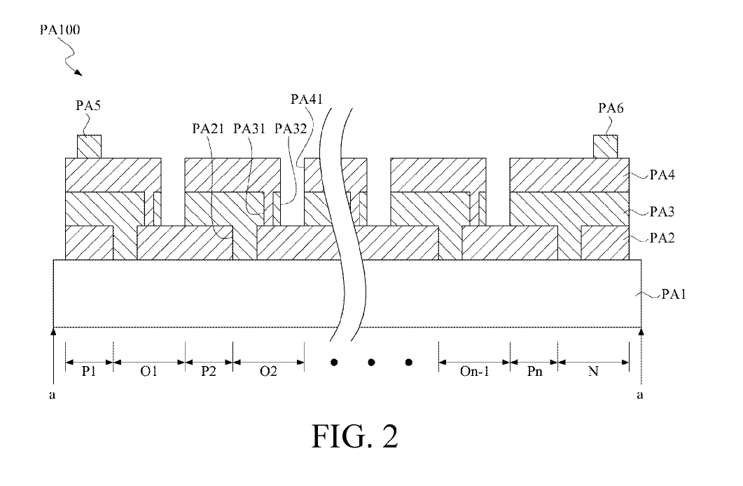

FIG. 3 is a schematic plan view of a solar cell according to a preferred embodiment of the present invention; and

FIG. 4 is a schematic cross-sectional view of segment b-b in FIG. 3.

### DETAILED DESCRIPTION OF THE INVENTION

In one aspect of the solar cell module of the present invention, the first electrode layer, the active layer and the second electrode layer in the ineffective zone are omitted to reduce unnecessary waste of materials and to relatively increase the power generation area. The solar cell module according to the present invention can be widely applied to various kinds of solar cells. Also, the battery units can be serially connected in numerous ways, so that the solar cell module according to the present invention can be implemented through various kinds of combinations. Therefore, details are not repeated here and only preferred embodiments are illustrated.

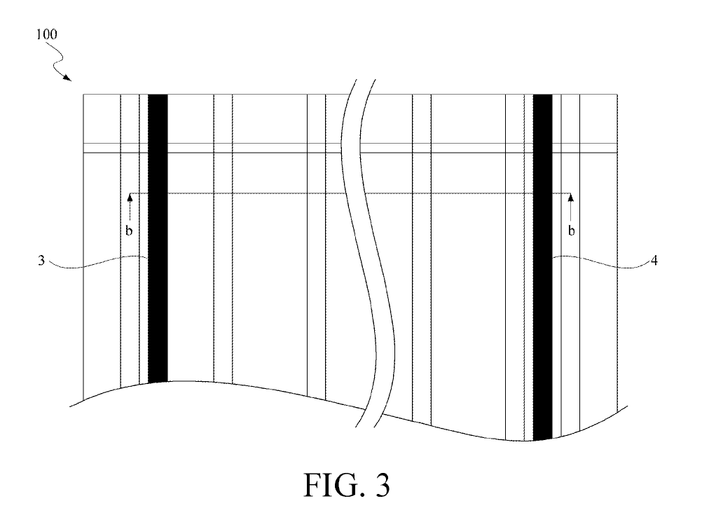

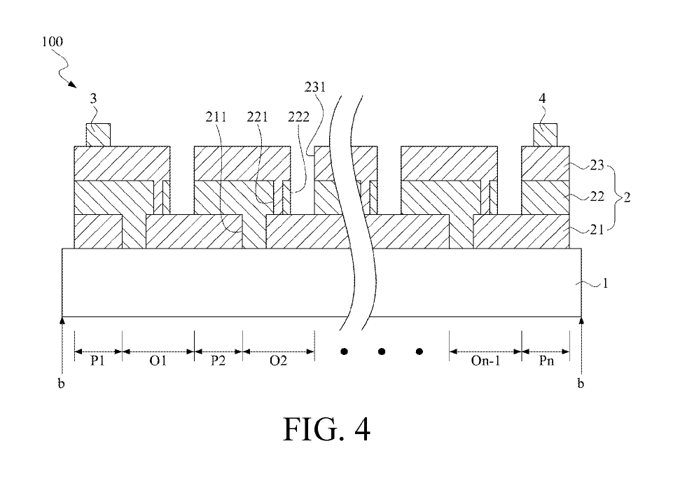

FIG. 3 is a schematic plan view of a solar cell according to a preferred embodiment of the present invention; and FIG. 4 is a schematic cross-sectional view of segment b-b in FIG. 3. As shown in FIG. 3 and FIG. 4, a solar cell module 100 includes a substrate 1, a battery unit 2, a first strip electrode 3 and a second strip electrode 4. The substrate 1 has a plurality of power generation zones P1 to Pn and a plurality of cutting zones O1 to On-1. The cutting zones O1-On-1 are located among the power generation zones P1-Pn.

The battery unit 2 is disposed on the power generation zones P1 to Pn and the cutting zones O1 to On-1 of the substrate 1, and the battery unit 2 includes a first electrode layer 21, an active layer 22 and a second electrode layer 23. The first electrode layer 21, the active layer 22 and the second electrode layer 23 are disposed in order on the power generation zones P1 to Pn and the cutting zones O1 to On-1 of the substrate 1. The first electrode layer 21 has a first opening 211 located at the cutting zones O1 to On-1; and the active layer 22 is disposed on the first electrode layer 21 and the substrate 1 expose from the first opening 211. The active layer 22 has a second opening 221 located at the cutting zones O1 to On-1 and a third opening 222 located at the cutting zones O1 to On-1; and the second electrode layer 23 is disposed on the active layer 22 and the first electrode layer 21 exposed from the second opening 221. The second electrode layer 23 has a fourth opening 231 in communication with the third opening 222.

The first strip electrode 3 is disposed on the second electrode layer 23 of the battery unit 2, and the first strip electrode 3 is located at the power generation zone P1, in which the power generation zone P1 is a first end power generation zone.

The second strip electrode 4 is disposed on the second electrode layer 23 of the battery unit 2, and the second strip electrode 4 is located at the power generation zone Pn, in which the power generation zone Pn is a second end power generation zone.

It can be known from the above description that the second strip electrode 4 is disposed in the power generation zone Pn, and therefore a current generated by the active layer 22 in the power generation zones P2 to Pn enables the second strip electrode 4 to transmit a current to an external load or electronic device in a centralized manner directly through the second electrode layer 23 without causing the waste of materials, thereby making full use of the materials and the power generation area. Furthermore, the first electrode layer 21 in the power generation zone P1 can be serially connected to the second electrode layer of another solar cell module, so that the active layer 22 located at the power generation zone P1 can generate a current.

In the preferred embodiment of the present invention, the first electrode layer 21, the active layer 22 and the second electrode layer 23 in the above description are formed in order, through chemical vapor deposition (CAD), on the power generation zones P1 to Pn and the cutting zones O1 to On-1 of the substrate 1. The substrate 1 may be formed by glass or transparent resin, and the transparent resin is one of polyethylene terephthalate (PET), polyethylene naphthalate (PEN), polycarbonate (PC), polyethersulfone (PES) or polyimide (PI).

Materials of the first electrode layer 21 and the second electrode layer 23 are transparent conductive oxide (TCO), which may be indium tin oxide (ITO), Al doped ZnO (AZO), indium zinc oxide (IZO) or other transparent conductive materials.

The active layer 22 is a Si-based stack structure, and the stack structure may be a mono-layer stack structure or a multi-layer stack structure, in which the mono-layer stack structure is a structure formed by a P-type semiconductor layer, an intrinsic layer and an n-type semiconductor layer; and the multi-layer stack structure is stacked by the mono-layer stack structure with different energy gaps. In the preferred embodiment of the present invention, the material of the active layer 22 is selected from amorphous silicon or microcrystalline silicon. Therefore, the above p-type semiconductor layer may be based on amorphous silicon or micro-crystalline silicon and doped with p-type dopants, in which the p-type dopants may be selected from the group of Group IIIA elements in the periodic table of elements, like boron, aluminum, gallium, indium or thallium. The n-type semiconductor layer may be based on amorphous silicon or micro-crystalline silicon and doped with n-type dopants, in which the n-type dopants may be selected from the group of Group VA elements in the periodic table of elements, like phosphorus, arsenic, antimony or bismuth.

Materials of the first strip electrode 3 and the second strip electrode 4 are metallic conductors, which may be, but not limited to, gold, silver or copper.

In other embodiments, the active layer 22 is a compound-based junction structure, and the junction structure may be a single junction structure or a multi-junction structure. It is preferred that the material of the active layer 22 is selected from compounds of Group IIIA-VA elements, compounds of Group IIA-VIA elements or multi-element compounds, in which the compounds of Group IIIA-VA elements may be gallium arsenide or indium phosphide, the compounds of Group IIA-VIA elements may be cadmium sulfide, cadmium telluride, or copper indium selenide, and the multi-element compounds may be copper indium potassium selenide compound.

It is believed that persons of ordinary skill in the art, when reading the above embodiments, can understand that in the solar cell module according to the present invention, the second strip electrode is disposed on the power generation zone and the first electrode layer, the active layer and the second electrode layer in the ineffective zone in the prior art are omitted, therefore, the waste of materials is reduced. Moreover, as the first electrode layer, the active layer and the second electrode layer in the ineffective zone are omitted, the power generation area of the power generation zone is relatively increased in the limited area of the substrate, thereby further improving the power generation efficiency of the solar cell module.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A solar cell module, comprising:
a substrate, having a plurality of power generation zones and at least one cutting zone, wherein the cutting zone is located among the power generation zones;
a battery unit, disposed on the power generation zones and the cutting zones of the substrate;
a first strip electrode, disposed on the battery unit, wherein the first strip electrode is located at a first end power generation zone of the power generation zones; and
a second strip electrode, disposed on the battery unit, wherein the second strip electrode is located at a second end power generation zone of the power generation zones.

2. The solar cell module according to claim 1, wherein
the battery unit comprises a first electrode layer, an active layer and a second electrode layer;
the first electrode layer, the active layer and the second electrode layer are disposed in sequence on the power generation zones and the cutting zones of the substrate; and
the first strip electrode and the second strip electrode are disposed on the second electrode layer.

3. The solar cell module according to claim 2, wherein
the first electrode layer has a first opening located at the cutting zone;
the active layer is disposed on the first electrode layer and the substrate exposed from the first opening, the active layer has a second opening located at the cutting zone and a third opening located at the cutting zone; and
the second electrode layer is disposed on the active layer and the first electrode layer exposed from the second opening; and the second electrode layer has a fourth opening in communication with the third opening.

4. The solar cell module according to claim 2, wherein the active layer is a Si-based stack structure and the stack structure is a mono-layer stack structure or a multi-layer stack structure.

5. The solar cell module according to claim 4, wherein a material of the active layer is selected from amorphous silicon or microcrystalline silicon.

6. The solar cell module according to claim 2, wherein the active layer is a compound-based junction structure and the junction structure is a single junction structure or a multi-junction structure.

7. The solar cell module according to claim 6, wherein a material of the active layer is selected from compounds of Group IIIA-VA elements, compounds of Group IIA-VIA elements or multi-element compounds.

8. The solar cell module according to claim 1, wherein materials of the first strip electrode and the second strip electrode are metallic conductors.
